(19) United States
(12) Patent Application Publication
(10) Pub. No.: US 2026/0293603 A1
(43) Pub. Date: Sep. 24, 2026

(54) FILM ADHESIVE, DICING/DIE ATTACH FILM, SEMICONDUCTOR DEVICE, AND PRODUCTION METHOD FOR SAME

(71) Applicant: Resonac Corporation, Minato-ku, Tokyo (JP)

(72) Inventors: Xue ZHAO, Tokyo (JP); Kohei TANIGUCHI, Tokyo (JP); Yuta HARADA, Tokyo (JP)

(21) Appl. No.: 19/477,488

(22) PCT Filed: Sep. 24, 2024
(86) PCT No.: PCT/JP2024/033926

§ 371 Date: Oct. 22, 2025

(30) Foreign Application Priority Data
Sep. 27, 2023 (JP) 2023-166182

(51) Int. Cl. H10P 72/70; C09J 5/06; C09J 7/30; C09J 163/00; H10P 58/00; H10W 72/00; H10W 72/30; H10W 90/00

(52) U.S. Cl. CPC H10P 72/7404; C09J 5/06; C09J 7/30; C09J 163/00; H10P 58/00; H10P 72/7416; H10P 72/7428; H10W 72/07338; H10W 72/352; H10W 90/734; C09J 2203/326; C09J 2301/208; C09J 2301/408; C09J 2301/50; H10W 72/884; H10W 90/7295; H10W 90/754

(57) ABSTRACT

A film adhesive including metal particles, an epoxy resin, a phenolic resin, and an elastomer, in which a content of the metal particles is 80.0% by mass or more based on a mass of the film adhesive, the epoxy resin includes a first epoxy resin that is liquid at 25° C. and a second epoxy resin that is solid at 25° C., and when the content of the metal particles is 100 parts by mass, the content of the first epoxy resin is 4.0 to 5.5 parts by mass.

### TECHNICAL FIELD

The present disclosure relates to a film adhesive, a dicing/die-bonding integrated film, a semiconductor device and a production method for the same.

### BACKGROUND ART

Conventionally, a semiconductor device is produced through the following steps. First, a semiconductor wafer is attached to an adhesive sheet for dicing, and in this state, the semiconductor wafer is singulated into semiconductor chips (a dicing step). Thereafter, a pickup step, a press-bonding step, a die-bonding step, and the like are performed. Patent Literature 1 discloses an adhesive film (a dicing/die-bonding integrated film) having both a function of fixing a semiconductor wafer in a dicing step and a function of bonding a semiconductor chip to a substrate in a die-bonding step. By singulating the semiconductor wafer and adhesive layer into pieces in the dicing step, an adhesive piece-attached semiconductor chip is obtained.

In recent years, a device called a power semiconductor device that performs power control and the like has been widely used. In the power semiconductor device, heat is likely to be generated due to a supplied current, and thus excellent heat dissipation is required. Patent Literature 2 discloses a film adhesive having higher heat dissipation after curing than the heat dissipation before curing.

### CITATION LIST

### Patent Literature

Patent Literature 1: Japanese Unexamined Patent Publication No. 2008-218571
Patent Literature 2: Japanese Patent No. 6396189

### SUMMARY OF INVENTION

### Technical Problem

Incidentally, in the production of a semiconductor device, as miniaturization and high integration of a semiconductor package have progressed, a film adhesive having high heat dissipation is required for suppressing heat generation of the semiconductor package. In order to achieve high heat dissipation, it is necessary to highly load a filler having high thermal conductivity. However, when a large amount of filler is blended in a film adhesive, a phenomenon occurs in which the adhesion to a polyethylene film as a covering film is decreases. There was a challenge in improving the deterioration in adhesion while maintaining high heat dissipation performance of the film adhesive.

The present disclosure provides a film adhesive that is useful for producing a semiconductor device having excellent in heat dissipation, and the film adhesive having excellent adhesion. Further, the present disclosure also provides a dicing/die-bonding integrated film including the film adhesive, as well as a semiconductor device and a production method for the same.

### Solution to Problem

In order to solve the above problems, the present inventors have optimized the amount of each resin component contained in a film adhesive under a condition of containing metal particles, and have intensively studied by focusing on a correlation between various parameters related to the film adhesive and adhesion, and as a result, have completed the following inventions.

The present disclosure relates to the following inventions.
[1]A film adhesive containing metal particles, an epoxy resin, a phenolic resin, and an elastomer, in which
   a content of the metal particles is 80.0% by mass or more based on a mass of the film adhesive,
   the epoxy resin includes a first epoxy resin that is liquid at 25° C. and a second epoxy resin that is solid at 25° C., and
   a content of the first epoxy resin is 4.0 to 5.5 parts by mass when the content of the metal particles is 100 parts by mass.
[2] The film adhesive according to [1], in which the content of the first epoxy resin is 1.5 parts by mass or more when the content of the second epoxy resin is 1 part by mass.
[3] The film adhesive according to [1] or [2], in which the content of the metal particles is 26 to 38 vol % based on a volume of the film adhesive.
[4] The film adhesive according to any one of [1] to [3], in which the metal particles are silver particles.
[5] The film adhesive according to any one of [1] to [4], in which an equivalent ratio of the epoxy resin to the phenolic resin is 1.2 or more.
[6] The film adhesive according to any one of [1] to [5] having a thickness of 5 to 40 μm.
[7] The film adhesive according to any one of [1] to [6], in which a thermal conductivity at 25° C.±1° C. after being thermally cured at 170° C. for 3 hours is 7 W/(m·K) or more.
[8]A dicing/die-bonding integrated film that has a laminate structure including a base material layer, a first adhesive layer, and a second adhesive layer in order, in which
   the second adhesive layer is composed of the film adhesive according to any one of [1] to [7].
[9] The dicing/die-bonding integrated film according to [8], further including a covering film provided to cover the second adhesive layer.
[10]A semiconductor device including:
   a semiconductor chip;
   a support member on which the semiconductor chip is mounted; and
   an adhesive member that is provided between the semiconductor chip and the support member and bonds the semiconductor chip and the support member to each other, in which
   the adhesive member is a cured article of the film adhesive according to any one of [1] to [7].
[11]A method for producing a semiconductor device, the method including:
   attaching the second adhesive layer of the dicing/die-bonding integrated film according to [8] or [9] to a semiconductor wafer;
   singulating a laminate of the semiconductor wafer and the second adhesive layer into pieces to obtain an adhesive piece-attached semiconductor chip composed of a semiconductor chip and an adhesive piece; and
   bonding the semiconductor chip to a support member via the adhesive piece.

### Advantageous Effects of Invention

According to the present disclosure, a film adhesive is provided that is useful for producing a semiconductor device having excellent heat dissipation, and the film adhesive having excellent adhesion. Further, according to the present disclosure, a dicing/die-bonding integrated film including a film adhesive, as well as a semiconductor device and a production method for the same, are provided.

### BRIEF DESCRIPTION OF DRAWINGS

FIG. 1 is a cross-sectional view schematically illustrating one embodiment of a film adhesive.

FIG. 2 is a cross-sectional view schematically illustrating one embodiment of a dicing/die-bonding integrated film.

FIG. 3 (a) to (f) in FIG. 3 are cross-sectional views schematically illustrating a series of steps for producing a semiconductor device.

FIG. 4 is a cross-sectional view schematically illustrating one embodiment of a semiconductor device.

### DESCRIPTION OF EMBODIMENTS

Hereinafter, embodiments of the present disclosure will be described with appropriate reference to the drawings. However, the present disclosure is not limited to the following embodiments. In the following embodiments, the components (including steps and the like) are not essential unless otherwise specified. Sizes of the components in the drawings are conceptual, and a relative relationship between the sizes of the components is not limited to that illustrated in the drawings.

In the present description, a numerical range indicated using “to” indicates a range including numerical values described before and after “to” as a minimum value and a maximum value, respectively. In the numerical range described in stages in the present description, an upper limit value or a lower limit value of a numerical range in a certain stage may be replaced with an upper limit value or a lower limit value of a numerical range in another stage. Further, in the numerical range described in the present description, the upper limit value or the lower limit value of the numerical range may be replaced with a value shown in the examples. Further, the upper limit value and the lower limit value described individually can be arbitrarily combined. Furthermore, in the present description, “(meth)acrylate” means at least one of acrylate and methacrylate corresponding thereto. The same applies to other similar expressions such as “(meth)acryloyl”. Further, “(poly)” means both cases where there is a prefix of “poly” and where there is no prefix of “poly”. Further, “A or B” only needs to include either A or B, and may include both A and B. Furthermore, the materials exemplified below may be used solely, or may be used in combination with two or more kinds thereof, unless otherwise specified. In a case where a plurality of substances corresponding to each component are present in a composition, the content of each component in the composition means a total amount of the plurality of substances present in the composition, unless otherwise specified.

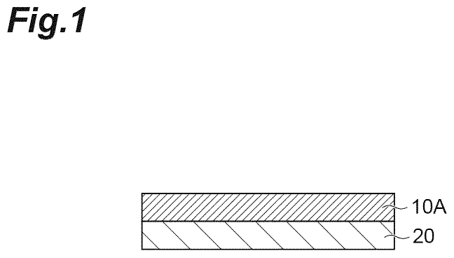

FIG. 1 is a cross-sectional view schematically illustrating a film adhesive according to the present embodiment. A film adhesive 10A illustrated in this figure is thermosetting, and is in a fully cured (C-stage) state after a curing treatment through a semi-cured (B-stage) state. The film adhesive 10A is provided on the supporting film 20. The film adhesive 10A is used as, for example, a die-bonding film used for bonding a semiconductor chip to a support member or for bonding semiconductor chips to each other.

The supporting film 20 is not particularly limited, and examples thereof include films of polytetrafluoroethylene, polyethylene, polypropylene, polymethylpentene, polyethylene terephthalate, and polyimide. The supporting film 20 may be subjected to release treatment.

The thickness of the supporting film 20 is, for example, 10 to 200 μm or 20 to 170 μm.

The film adhesive 10A contains metal particles, an epoxy resin, a phenolic resin, and an elastomer, the content of the metal particles is 80.0% by mass or more based on the mass of the film adhesive, the epoxy resin includes a first epoxy resin that is liquid at 25° C. and a second epoxy resin that is solid at 25° C., and when the content of the metal particles is 100 parts by mass, the content of the first epoxy resin is 4.0 to 5.5 parts by mass. By using the first epoxy resin and the second epoxy resin in combination, excellent adhesion of the film adhesive can be achieved even when the content of the metal particles is 80.0% by mass or more. From a viewpoint of achieving more excellent adhesion, when the content of the second epoxy resin is 1 part by mass, the content of the first epoxy resin may be 1.5 parts by mass or more, 1.5 to 2.0 parts by mass, or 1.6 to 1.8 parts by mass. When the content of the metal particles is 100 parts by mass, the content of the second epoxy resin is, for example, 2.0 to 4.0 parts by mass, and may be 2.1 to 3.8 parts by mass or 2.2 to 3.5 parts by mass.

The film adhesive 10A may further contain a coupling agent and a curing accelerator in addition to the above components. Hereinafter, in some cases, the metal particles are referred to as “component (A)”, the thermosetting resin is referred to as “component (B)”, the curing agent is referred to as “component (C)”, the elastomer is referred to as “component (D)”, the coupling agent is referred to as “component (E)”, and the curing accelerator is referred to as “component (F)”. The component will be described below.

### Component (A): Metal Particles

The metal particles as the component (A) are components for enhancing heat dissipation when the film adhesive is applied to a semiconductor device.

Examples of the component (A) include particles containing metals such as aluminum, nickel, tin, bismuth, indium, zinc, iron, copper, silver, gold, palladium, and platinum. The component (A) may be metal particles composed of one kind of metal or may be metal particles composed of two or more kinds of metals. The metal particles composed of two or more kinds of metals may be metal-coated metal particles in which surfaces of the metal particles are coated with a metal different from the metal particles. The component (A) may be, for example, conductive particles.

The conductive particles may be, for example, metal particles composed of a metal having an electrical conductivity (0° C.) of 40×10⁶ S/m or more. By using such conductive particles, heat dissipation can be further improved. Examples of the metal having an electrical conductivity (0° C.) of 40×10⁶ S/m or more include gold (49×10⁶ S/m), silver (67×10⁶ S/m), and copper (65×10⁶ S/m). The electrical conductivity (0° C.) may be 45×10⁶ S/m or more or 50×10⁶ S/m or more. In other words, the conductive particles (or metal particles as the component (A)) are preferably metal particles composed of silver and/or copper.

The conductive particles may be, for example, metal particles composed of a metal having a thermal conductivity (20° C.) of 250 W/(m·K) or higher. By using such conductive particles, heat dissipation can be further improved. Examples of metals having a thermal conductivity (20° C.) of 250 W/(m·K) or higher include gold (295 W/(m·K)), silver (418 W/(m·K)), and copper (372 W/(m·K)). The thermal conductivity (20° C.) may be 300 W/(m K) or higher, or 350 W/(m·K) or higher. In other words, the conductive particles (or metal particles as the component (A)) are preferably metal particles composed of silver and/or copper.

The component (A) may be silver particles, as they are excellent in electric conductivity and thermal conductivity and are resistant to oxidation. The silver particles may be, for example, particles composed of silver (particles composed solely of silver) or silver-coated metal particles in which the surfaces of metal particles (copper particles or the like) are coated with silver. Examples of the silver-coated metal particles include silver-coated copper particles. The component (A) may be particles composed of silver.

The silver particles as the component (A) are not particularly limited, and examples thereof include silver particles produced by a reduction method (silver particles produced by a liquid phase (wet) reduction method using a reducing agent) and silver particles produced by an atomizing method. The silver particles as the component (A) may be silver particles produced by a reduction method.

In a liquid phase (wet) reduction method using a reducing agent, a surface treatment agent (lubricant) is usually added from a viewpoint of preventing agglomeration or fusion and controlling a particle diameter. The surfaces of silver particles produced by a liquid phase reduction method (wet reduction method) using a reducing agent are coated with a surface treating agent (lubricant). Therefore, the silver particles produced by a reduction method can also be said to be silver particles surface-treated with a surface treatment agent. Examples of the surface treatment agent include fatty acid compounds such as oleic acid (melting point: 13.4° C.), myristic acid (melting point: 54.4° C.), palmitic acid (melting point: 62.9° C.), and stearic acid (melting point: 69.9° C.); fatty acid amide compounds such as oleic acid amide (melting point: 76° C.) and stearic acid amide (melting point: 100° C.); aliphatic alcohol compounds such as pentanol (melting point: −78° C.), hexanol (melting point: −51.6° C.), oleyl alcohol (melting point: 16° C.), and stearyl alcohol (melting point: 59.4° C.); and aliphatic nitrile compounds such as oleonitrile (melting point: −1° C.). The surface treatment agent may be a surface treatment agent having a low melting point (for example, a melting point of 100° C. or lower) and high solubility in organic solvents.

A shape of the component (A) is not particularly limited, and may be, for example, a flake shape, a resin shape, a spherical shape, or the like, or may be a spherical shape. When the shape of the component (A) is spherical, a surface roughness (Ra) of the film adhesive tends to be easily reduced.

The component (A) may be metallic particles (preferably, conductive particles, more preferably silver particles) having an average particle diameter of 0.01 to 10 μm. When the average particle diameter of the metal particles is 0.01 μm or more, there is a tendency that effects are exhibited such as that an increase in viscosity when an adhesive varnish is produced can be prevented, a desired amount of metal particles can be contained in the film adhesive, and wettability of the film adhesive to an adherend can be secured and exhibit better adhesive properties. When the average particle diameter of the metal particles is 10 μm or less, there is a tendency that the film formability is more excellent, and the heat dissipation due to the addition of the metal particles can be further improved. Further, when the average particle diameter of the metal particles is 10 μm or less, there is a tendency that the thickness of the film adhesive can be further reduced, and the semiconductor chip can be highly laminated. In addition, it tends to be possible to prevent cracks in the semiconductor chip caused by the metal particles protruding from the film adhesive. The average particle diameter of the metal particles as the component (A) may be 0.1 μm or more, 0.3 μm or more, or 0.5 μm or more, and may be 8.0 μm or less, 7.0 μm or less, 6.0 μm or less, 5.0 μm or less, 4.0 μm or less, or 3.0 μm or less.

Note that, in the present description, the average particle diameter of the metal particles as the component (A) means a particle diameter when a proportion (volume fraction) to the volume of the total metal particles is 50% (laser 50% particle diameter (D50)). The average particle diameter (D50) can be determined by measuring a suspension of metal particles in water by a laser scattering method using a laser scattering type particle diameter measurement device (for example, Microtrac).

According to the study of the present inventors, it has been found that in a case where the film adhesive contains the component (A), a shear viscosity and a storage elastic modulus of the film adhesive at 110° C. have a high correlation with the goodness of step embedding properties. A film adhesive satisfying at least one of the following conditions (i) and (ii) can be used to produce a semiconductor device having excellent heat dissipation and having excellent step embedding properties. The film adhesive may satisfy both the conditions (i) and (ii).
Condition (i): The shear viscosity at 110° C. is 35000 Pa·s or less.
Condition (ii): The storage elastic modulus at 265° C. is 700 MPa or less.

The shear viscosity of the film adhesive at 110° C. is, for example, 35000 Pa·s or less, and may be 28000 Pa·s or less, 26000 Pa·s or less, 25000 Pa·s or less, 24000 Pa·s or less, 22000 Pa·s or less, 20000 Pa·s or less, 18000 Pa·s or less, or 15000 Pa·s or less. A lower limit of the shear viscosity of the film adhesive at 110° C. is not particularly limited, but may be, for example, 3000 Pa·s or more, 5000 Pa·s or more, 6000 Pa·s or more, or 7000 Pa·s or more.

The shear viscosity at 110° C. means a value measured by the following method. First, the film adhesive is cut into a predetermined size to prepare a plurality of film pieces. Next, these film pieces are laminated on a hot plate at 70° C. using a rubber roll to prepare a laminate having a thickness of 300 μm. Then, this laminate is punched with the φ10 mm punch to obtain a sample. The shear viscosity of this sample is measured under the following conditions using a rotary viscoelasticity measurement device (manufactured by TA Instruments Japan Inc., trade name: ARES-RDA). The value of the shear viscosity at a temperature of 110° C. is defined as the shear viscosity at 110° C. Note that, during gap setting, the gap is adjusted so that the load applied to the sample is 10 g.

### (Measurement Conditions)

Disk plate: aluminum, 8 mm φ
Measurement frequency: 1 Hz
Temperature rising rate: 5° C./min
Strain: 5%
Measurement temperature: 35 to 180° C.
Initial load: 10 g

The storage elastic modulus of the film adhesive at 35° C. and 265° C. is 700 MPa or less, and may be 650 MPa or less, 600 MPa or less, 500 MPa or less, 450 MPa or less, or 400 MPa or less. The lower limit of the storage elastic modulus of the film adhesive at 110° C. is not particularly limited, but may be, for example, 250 MPa or more, 300 MPa or more, or 350 MPa or more.

The storage elastic modulus at 110° C. means a value measured by the following method. First, the film adhesive is cut into a predetermined size to prepare a plurality of film pieces. Next, these film pieces are laminated on a hot plate at 70° C. using a rubber roll to prepare a laminate having a thickness of 200 μm. Then, this laminate is thermally cured by heating at 110° C. for 1 hour, and subsequently heating at 170° C. for 3 hours. The cured article thus obtained is cut into pieces of 4 mm×30 mm to obtain a sample. The storage elastic modulus of this sample is measured under the following conditions using a rotary viscoelasticity measurement device (for example, manufactured by TA Instruments Japan Inc., trade name: ARES-RDA). The values at temperatures of 35° C. and 110° C. are defined as the storage elastic modulus at 35° C. and 110° C., respectively.

### (Measurement Conditions)

Basic frequency: 10 Hz
Measurement mode: strain dependence
Temperature rising rate: 3° C./min
Measurement temperature: 30 to 270° C.

The value of the shear viscosity of the film adhesive at 110° C. can be reduced, for example, by the following method.

Reduce the content of the component (A) (increasing the content of components other than the component (A)).

Increase the ratio of the total amount of the component (B) and (C) to the total amount of the component (A), (B), (C), and (D).

Use the component (B) or the component (C) having a softening point of 90° C. or lower.

Use the component (D) having a low molecular weight.

The content of the component (A) is 80.0% by mass or more, and may be 81.0% by mass or more, 82.0% by mass or more, or 83.0% by mass or more, based on the total mass of the film adhesive. When the content of the component (A) is 80.0% by mass or more, the thermal conductivity of the film adhesive tends to be improved, and the heat dissipation of the semiconductor device tends to be further improved.

The content of the component (A) may be, for example, 85.0% by mass or less, 84.5% by mass or less, or 84.0% by mass or less, based on the total mass of the film adhesive. When the content of the component (A) is 85.0% by mass or less, the film adhesive can more sufficiently include other components. This makes it easier to adjust the shear viscosity and storage elastic modulus of the film adhesive at 110° C. in predetermined ranges, and the film adhesive tends to be more excellent in embedding properties for steps.

The content of the component (A) may be 26.0 vol % or more, 27.0 vol % or more, 28.0 vol % or more, 29.0 vol % or more, 30.0 vol % or more, 31.0 vol % or more, or 32.0 vol % or more, based on the total mass of the film adhesive. When the content of the component (A) is 26.0 vol % or more based on the total mass of the film adhesive, the thermal conductivity of the film adhesive tends to be improved, and the heat dissipation of the semiconductor device tends to be further improved. The content of the component (A) may be, for example, 38.0% by volume or less, 37.0 vol % or less, 36.5 vol % or less, or 36.0 vol % or less, based on the total mass of the film adhesive. When the content of the component (A) is 38.0 vol % or less based on the total mass of the film adhesive, other components can be more sufficiently contained in the film adhesive. This makes it easier to adjust the shear viscosity at 110° C. and the storage elastic modulus at 265° C. of the film adhesive in predetermined ranges, and the film adhesive tends to be more excellent in embedding properties for steps.

The content (% by volume) of the component (A) can be calculated, for example, from the following formula (I), where a density of the film adhesive is x (g/cm³), a density of the component (A) is y (g/cm³), and a mass ratio of the component (A) in the film adhesive is z (% by mass). Note that, the mass ratio of the component (A) in the film adhesive can be determined, for example, by performing thermogravimetric analysis using a thermogravimetric-differential thermal analyzer (TG-DTA). Further, the density of the film adhesive and the component (A) can be determined by measuring the weight and specific gravity using a hydrometer.

$$Content of co mponent ( A ) ( \% by volume ) = ( x / y ) \times x ( I )$$

Measurement conditions of TG-DTA: temperature range 30 to 600° C. (heating rate 30° C./min), maintained at 600° C. for 20 minutes
Air flow rate: 300 mL/min
Thermogravimetric differential thermal analyzer: TG/DTA220 manufactured by Seiko Instruments Inc.
Hydrometer: EW-300SG manufactured by Alfa Mirage Co., Ltd.

### Component (B): Thermosetting Resin

The component (B) is a component having a property of forming a three-dimensional network between molecules by heating or the like and curing, and is a component exhibiting adhesive properties after curing. The component (B) may be an epoxy resin. The epoxy resin can be used without particular limitation as long as it has an epoxy group in the molecule. The epoxy resin may have at least two epoxy groups in the molecule.

Examples of the epoxy resin include a bisphenol A type epoxy resin, a bisphenol F type epoxy resin, a bisphenol S type epoxy resin, a phenol novolac type epoxy resin, a cresol novolac type epoxy resin, a bisphenol A novolac type epoxy resin, a bisphenol F novolac type epoxy resin, a stilbene type epoxy resin, a triazine skeleton-containing epoxy resin, a fluorene skeleton-containing epoxy resin, a triphenol methane type epoxy resin, a biphenyl type epoxy resin, a xylylene type epoxy resin, a biphenyl aralkyl type epoxy resin, a naphthalene type epoxy resin, a dicyclopentadiene type epoxy resin, a polyfunctional phenols, and diglycidyl ether compounds of polycyclic aromatics such as anthracene.

The epoxy resin may contain an epoxy resin having a softening point of 90° C. or lower. By containing an epoxy resin having a softening point of 90° C. or less, the epoxy resin is sufficiently liquefied at 110° C., which tends to make it easier to adjust the shear viscosity of the film adhesive at 110° C. within a predetermined range.

Note that, in the present description, the softening point means a value measured by a Ring-and-Ball method in accordance with JIS K7234.

The epoxy resin includes an epoxy resin (hereinafter, sometimes referred to as a “first epoxy resin”) that is liquid at 25° C. and an epoxy resin (hereinafter, sometimes referred to as a “second epoxy resin”) that is solid at 25° C. The content of the first epoxy resin and the second epoxy resin in the epoxy resin is, for example, 90% by mass or more, and may be 95% by mass or more. The epoxy resin may be composed solely of the first epoxy resin and the second epoxy resin.

When a part of the epoxy resin is the first epoxy resin, the surface roughness (Ra) of the film adhesive tends to be readily improved. When the content of the second epoxy resin is 1 part by mass, the content of the first epoxy resin may be 1.5 or more, or 1.6 or more, or may be 2.0 or less, 1.9 or less, or 1.8 or less. By setting the content as described above, the adhesion of the film adhesive is improved, and as a result, peeling of the covering film can be highly suppressed. Examples of commercially available products of the first epoxy resin include EXA-830CRP (trade name, manufactured by DIC Corporation) and YDF-8170C (trade name, Nippon Steel Chemical & Material Co., Ltd.).

An epoxy equivalent of the epoxy resin is not particularly limited, but may be 90 to 300 g/eq or 110 to 290 g/eq. When the epoxy equivalent of the epoxy resin is in such a range, it tends to be easy to secure the fluidity of the adhesive varnish when forming the film adhesive while maintaining a bulk strength of the film adhesive.

The content of the component (B) may be 1.0% by mass or more, 3.0% by mass or more, 5.0% by mass or more, or 7.0% by mass or more, and may be 15.0% by mass or less, 14.0% by mass or less, 13.0% by mass or less, 12.0% by mass or less, or 11.0% by mass or less, based on the total mass of the film adhesive.

The equivalent ratio of the epoxy resin to the phenolic resin is not particularly limited, but may be 1.2 or more, or 1.3 or more, and may be 1.5 or less.

### Component (C): Curing Agent

The component (C) is a component that acts as a curing agent for the component (B), and is specifically an epoxy resin curing agent. Examples of the component (C) include a phenolic resin (phenolic curing agent), an acid anhydride curing agent, an amine curing agent, an imidazole curing agent, a phosphine curing agent, an azo compound, and an organic peroxide. In a case where the component (B) is an epoxy resin, the component (C) may be a phenolic resin from a viewpoint of handleability, storage stability, and curing properties.

The phenolic resin can be used without particular limitation as long as it has a phenolic hydroxyl group in the molecule. Examples of the phenolic resin include a novolac type phenolic resin obtained by condensation or co-condensation of a phenol such as phenol, cresol, resorcinol, catechol, bisphenol A, bisphenol F, phenylphenol, or aminophenol and/or a naphthol such as a-naphthol, P-naphthol, or dihydroxynaphthalene with a compound having an aldehyde group such as formaldehyde in the presence of an acidic catalyst; a phenol aralkyl resin synthesized from a phenol such as allylated bisphenol A, allylated bisphenol F, allylated naphthalenediol, phenol novolac, or phenol and/or a naphthol with dimethoxyparaxylene or bis(methoxymethyl)biphenyl; a naphthol aralkyl resin; a biphenylaralkyl type phenolic resin; and a phenyl aralkyl type phenolic resin.

The phenolic resin may contain a phenolic resin having a softening point of 90° C. or lower. By containing a phenolic resin having a softening point of 90° C. or less, the phenolic resin is sufficiently liquefied at 110° C., which tends to make it easy to adjust the shear viscosity and storage elastic modulus of the film adhesive at 110° C. in predetermined ranges.

A hydroxyl equivalent of the phenolic resin may be 40 to 300 g/eq, 70 to 290 g/eq, or 100 to 280 g/eq. When the hydroxyl equivalent of the phenolic resin is 40 g/eq or more, the storage elastic modulus of the film adhesive tends to be further improved, and when the hydroxyl equivalent of the phenolic resin is 300 g/eq or less, it becomes possible to prevent defects due to foaming, generation of outgas, and the like.

The ratio of the epoxy equivalent of the epoxy resin as the component (B) to the hydroxyl equivalent of the phenolic resin as the component (C) (epoxy equivalent of epoxy resin as component (B)/hydroxyl group equivalent of phenolic resin as component (C)) may be 0.30/0.70 to 0.70/0.30, 0.35/0.65 to 0.65/0.35, 0.40/0.60 to 0.60/0.40, or 0.45/0.55 to 0.55/0.45 from the viewpoint of curing properties. When the equivalent ratio is 0.30/0.70 or more, more sufficient curing properties tend to be obtained. When the equivalent ratio is 0.70/0.30 or less, the viscosity can be prevented from becoming too high, and more sufficient fluidity can be obtained.

The content of the component (C) may be 1.0% by mass or more, 3.0% by mass or more, 4.0% by mass or more, or 5.0% by mass or more, and may be 15.0% by mass or less, 12.0% by mass or less, 10.0% by mass or less, or 9.0% by mass or less, based on the total mass of the film adhesive.

The total content of the component (B) and the component (C) may be 13.0% by mass or more based on the total mass of the film adhesive. When the total content of the component (B) and the component (C) is 13.0% by mass or more, it becomes easier to adjust the shear viscosity and storage elastic modulus of the film adhesive at 110° C. to predetermined ranges, and the film adhesive tends to be more excellent in embedding properties for steps. The total content of the component (B) and the component (C) may be 13.2% by mass or more, 13.5% by mass or more, 14.0% by mass or more, 14.5% by mass or more, 15.0% by mass or more, or 15.5% by mass or more, based on the total mass of the film adhesive. The total content of the component (B) and the component (C) may be 30.0% by mass or less, 25.0% by mass or less, 23.0% by mass or less, 22.0% by mass or less, 21.0% by mass or less, 20.0% by mass or less, or 18.0% by mass or less, based on the total mass of the film adhesive.

### Component (D): Elastomer

Examples of the component (D) include a polyimide resin, an acrylic resin, a urethane resin, a polyphenylene ether resin, a polyetherimide resin, a phenoxy resin, and a modified polyphenylene ether resin. The component (D) may be any of these resins having a crosslinkable functional group, or may be an acrylic resin having a crosslinkable functional group. Here, the acrylic resin means a (meth)acrylic (co)polymer containing a constituent unit derived from a (meth)acrylate ((meth)acrylic acid ester). The acrylic resin may be a (meth)acrylic (co)polymer containing a constituent unit derived from a (meth)acrylate having a crosslinkable functional group such as an epoxy group, an alcohol or phenolic hydroxyl group, or a carboxy group. Further, the acrylic resin may be an acrylic rubber such as a copolymer of (meth)acrylate and acrylonitrile. These elastomers may be used solely or in combination with two or more kinds thereof.

Examples of commercially available products of the acrylic resin include SG-P3 solvent modified products, SG-70L, SG-708-6, WS-023 EK30, SG-280 EK23, HTR-860P-3, HTR-860P-3CSP, and HTR-860P-3CSP-3DB (all manufactured by Nagase ChemteX Corporation).

A glass transition temperature (Tg) of the elastomer as the component (D) may be −50 to 50° C. or −30 to 20° C. When the Tg is −50° C. or higher, the tack of the film adhesive is lowered, so that the handing property tends to be further improved. When the Tg is 50° C. or lower, the fluidity of the adhesive varnish tends to be more sufficiently secured when the film adhesive is formed. Here, the Tg of the elastomer as the component (D) means a value measured using DSC (thermal differential scanning calorimeter) (for example, manufactured by Rigaku Corporation, trade name: Thermo Plus 2).

A weight-average molecular weight (Mw) of the elastomer as the component (D) may be 50000 to 1.6 million, 100000 to 1.4 million, or 300000 to 1.2 million. When the glass transition temperature of the elastomer as the component (D) is 50000 or more, film-forming properties tend to be more excellent. When the weight-average molecular weight of the component (D) is 1.6 million or less, the fluidity of the adhesive varnish when the film adhesive is formed tends to be better. Here, the Mw of the elastomer as the component (D) means a value obtained by performing measurement by gel permeation chromatography (GPC) and performing conversion using a calibration curve of standard polystyrene.

A measurement device and measurement conditions and the like for the Mw of the elastomer as the component (D) are, for example, as follows.
Pump: L-6000 (manufactured by Hitachi, Ltd.)
Column: a column in which Gelpack GL-R440 (manufactured by Hitachi Chemical Company, Ltd.), Gelpack GL-R450 (manufactured by Hitachi Chemical Company, Ltd.), and Gelpack GL-R400M (manufactured by Hitachi Chemical Company, Ltd.) (each with 10.7 mm (diameter)×300 mm) are connected in this order
Eluent: tetrahydrofuran (hereinafter referred to as “THF”)
Sample: a solution in which 120 mg of a sample is dissolved in 5 mL of THF
Flow rate: 1.75 m/min

The content of the component (D) may be 15.0% by mass or less, 12.0% by mass or less, 10.0% by mass or less, or 9.0% by mass or less, based on the total mass of the film adhesive. When the content of the component (D) is 15.0% by mass or less based on the total mass of the film adhesive, it is possible to prevent the viscosity from becoming excessively high and the step embedding properties from being deteriorated. The lower limit of the content of the component (D) may be 1.0% by mass or more, 1.5% by mass or more, 2.0% by mass or more, 2.5% by mass or more, or 2.8% by mass or more based on the total mass of the film adhesive from a viewpoint of film processability.

### Component (E): Coupling Agent

The component (E) may be a silane coupling agent. Examples of the silane coupling agent include γ-ureidopropyltriethoxysilane, γ-mercaptopropyltrimethoxysilane, 3-phenylaminopropyltrimethoxysilane, and 3-(2-aminoethyl)aminopropyltrimethoxysilane.

### Component (F): Curing Accelerator

Examples of the component (F) include imidazoles and derivatives thereof, organophosphorus compounds, secondary amines, tertiary amines, and quaternary ammonium salts. Among them, the component (F) may be an imidazole compound and a derivative thereof from a viewpoint of reactivity.

Examples of the imidazole include 2-methylimidazole, 1-benzyl-2-methylimidazole, 1-cyanoethyl-2-phenylimidazole, and 1-cyanoethyl-2-methylimidazole. These may be used solely or in combination with two or more kinds thereof.

The film adhesive may further contain other components. Examples of other components include a pigment, an ion scavenger, and an antioxidant.

The total content of the component (E), the component (F), and other components may be 0.005 to 10% by mass based on the total mass of the film adhesive.

### [Method for Producing Film Adhesive]

The method for producing the film adhesive 10A illustrated in FIG. 1 is not particularly limited, but for example, the film adhesive can be obtained by a production method including a step (mixing step) of mixing a raw material varnish containing the component (A) and an organic solvent to prepare an adhesive varnish containing the component (A), the organic solvent, the component (B), and the component (C), and a step (forming step) of forming a film adhesive using the adhesive varnish. The adhesive varnish may further contain the component (D), the component (E), the component (F), other components, and the like as necessary.

### (Mixing Step)

The mixing step is a step of mixing a raw material varnish containing the component (A) and the organic solvent to prepare an adhesive varnish containing the component (A), the organic solvent, the component (B), and the component (C).

The organic solvent is not particularly limited as long as it can dissolve components other than the component (A). Examples of the organic solvent include aromatic hydrocarbons such as toluene, xylene, mesitylene, cumene, and p-cymene.; aliphatic hydrocarbons such as hexane and heptane; cyclic alkanes such as methylcyclohexane; cyclic ethers such as tetrahydrofuran and 1,4-dioxane; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, γ-butyrolactone, butyl carbitol acetate, and ethyl carbitol acetate; carbonic acid esters such as ethylene carbonate and propylene carbonate; amides such as N,N-dimethylformamide, N,N-dimethylacetamide, and N-methyl-2-pyrrolidone, and alcohols such as butyl carbitol and ethyl carbitol. These may be used solely or in combination with two or more kinds thereof. Among them, from the viewpoint of the solubility and boiling point of the surface treatment agent, the organic solvent may be N,N-dimethylformamide, N,N-dimethylacetamide, N-methyl-2-pyrrolidone, butyl carbitol, ethyl carbitol, butyl carbitol acetate, ethyl carbitol acetate, or cyclohexanone. A solid component concentration in the raw material varnish may be 10 to 80% by mass based on the total mass of the raw material varnish.

The raw material varnish can be obtained, for example, by adding each component to a container used in a mixer. In this case, the order of addition of each component is not particularly limited, and can be appropriately set according to the properties of each component.

Mixing can be performed by appropriately combining ordinary mixers such as a Homo Disper, a Three-One Motor, a mixing rotor, a planetary mixer, and a grinding machine. The mixer may include heating equipment such as a heater unit capable of controlling temperature conditions of the raw material varnish or the adhesive varnish. In a case where a homodisper is used for mixing, a rotation speed of the homodisper may be 4000 rpm or more.

A mixing temperature in the mixing step is not particularly limited, but may be 50° C. or above. The mixing temperature in the mixing step may be increased by a heating equipment or the like as necessary. According to the study of the present inventors, it has been found that when the mixing temperature in the mixing step is 50° C. or higher, for example, in a case where silver particles (preferably, silver particles produced by a reduction method) are used, the resulting film adhesive can contain a sintered body of silver particles in a C-stage state. Such a phenomenon more remarkably appears when the silver particles produced by a reduction method are used as the component (A). The reason why such a phenomenon occurs is not necessarily clear, but the present inventors consider as follows. The silver particles (produced by a liquid phase (wet) reduction method using a reducing agent) as the component (A) are usually coated with a surface treatment agent (lubricant). Here, it is presumed that when the mixing temperature in the mixing step is 50° C. or higher, the surface treatment agent covering the silver particles is disassociated, making the silver surface (in a reduced state) more easily exposed. Furthermore, since the silver particles having such exposed silver surfaces easily come into direct contact with each other, it is presumed that when heating is performed under the condition of curing the film adhesive, the silver particles are easily undergo sintering to form a sintered body of silver particles. As a result, it is considered that the film adhesive contains a sintered body of silver particles in the C-stage state. Note that, the silver particles produced by an atomization method are covered with a silver oxide film on the surface of the silver particles due to the characteristics in the production method. According to the study of the present inventors, it has been confirmed that in a case where the silver particles produced by an atomization method are used, the resulting film adhesive is unlikely to contain a sintered body of silver particles in the C-stage state even when the mixing temperature in the mixing step is 50° C. or higher. The mixing temperature in the mixing step may be 55° C. or higher, 60° C. or higher, 65° C. or higher, or 70° C. or higher. An upper limit of the mixing temperature in the mixing step may be, for example, 120° C. or lower, 100° C. or lower, or 80° C. or lower. A mixing time in the mixing step may be, for example, 1 minute or more, 5 minutes or more, or 10 minutes or more, and may be 60 minutes or less, 40 minutes or less, or 20 minutes or less.

The component (B), the component (C), the component (D), the component (E), the component (F), or other components can be contained in the adhesive varnish at an optional stage according to the properties of each component. These components may be contained in the adhesive varnish by, for example, being added to the raw material varnish before the mixing step, or may be contained by being added to the adhesive varnish after the mixing step. The component (B) and the component (C) are preferably contained in the adhesive varnish by being added to the base varnish before the mixing step. The component (D) may be contained in the adhesive varnish by being added to the raw material varnish before the mixing step, or may be contained by being added to the adhesive varnish after the mixing step. The component (E) and the component (F) are preferably contained by addition to the adhesive varnish after the mixing step. In a case where the additive is added to the adhesive varnish after the mixing step, the additive may be mixed, for example, under a temperature condition below 50° C. (for example, room temperature (25° C.) after the addition. The conditions in this case may be 0.1 to 48 hours under room temperature (25° C.)).

In one embodiment, the mixing step may be a step of mixing a raw material varnish containing the component (A), the component (B), the component (C), the component (D), and an organic solvent, preferably at a mixing temperature of 50° C. or higher, to prepare an adhesive varnish containing the component (A), the component (B), the component (C), the component (D), and the organic solvent.

In this way, an adhesive varnish containing the component (A), the organic solvent, the component (B), and the component (C) can be prepared. After the preparation of the adhesive varnish, bubbles in the varnish may be removed by vacuum degassing or the like.

The solid component concentration in the adhesive varnish may be 10 to 80% by mass based on the total mass of the adhesive varnish.

### (Forming Step)

The forming step is a step of forming a film adhesive using an adhesive varnish. Examples of the method for forming the film adhesive include a method of applying the adhesive varnish to a supporting film.

As a method of applying the adhesive varnish to the supporting film, a known method can be used, and examples thereof include a knife coat method, a roll coat method, a spray coat method, a gravure coat method, a bar coat method, and a curtain coat method.

After the adhesive varnish is applied to the supporting film, if necessary, the organic solvent may be heated and dried. The heating and drying is not particularly limited as long as the organic solvent used is sufficiently volatilized, but for example, the heating and drying temperature may be 50 to 200° C., and the heating and drying time may be 0.1 to 30 minutes. The heating and drying may be performed in stages at different heating and drying temperatures or heating and drying times.

In this way, the film adhesive 10A can be obtained. The thickness of the film adhesive 10A may be appropriately adjusted according to the application, and may be, for example, not less than 3 μm, not less than 5 μm, or not less than 10 μm, and may be not more than 200 μm, not more than 100 μm, not more than 50 μm, not more than 40 μm, or not more than 30 μm.

In the C-stage state, the thermal conductivity (25° C.±1C) of the film adhesive 10A may be 1.5 W/(m·K) or more. When the thermal conductivity is 1.5 W/(m·K) or more, the heat dissipation property of the semiconductor device tends to be more excellent. The thermal conductivity may be 2.0 W/(m K) or more, 2.5 W/(m K) or more, 3.0 W/(m·K) or more, 3.5 W/(m·K) or more, 4.0 W/(m·K) or more, 4.5 W/(m·K) or more, or 5.0 W/(m·K) or more. The upper limit of the thermal conductivity (25° C.±1° C.) of the film adhesive 10A in the C-stage state is not particularly limited, but may be 30 W/(m·K) or less. Note that, in the present description, the thermal conductivity means a value calculated by the method described in the examples. Further, the conditions for curing the film adhesive 10A into the C-stage state can be, for example, a heating temperature of 170° C. and a heating time of 3 hours.

### [Dicing/Die-Bonding Integrated Film and Method for Producing the Same]

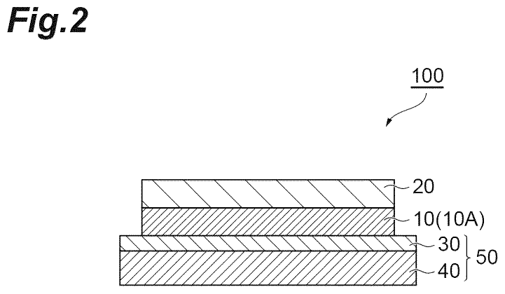

FIG. 2 is a schematic cross-sectional view illustrating one embodiment of a dicing/die-bonding integrated film. A dicing/die-bonding integrated film 100 illustrated in FIG. 2 includes a base material layer 40, a first adhesive layer 30, and a second adhesive layer 10 made of a film adhesive 10A in this order. It can also be said that the dicing/die-bonding integrated film 100 includes a dicing tape 50 including a base material layer 40 and a first adhesive layer 30 provided on the base material layer 40, and a second adhesive layer 10 provided on the first adhesive layer 30 of the dicing tape 50. The dicing/die-bonding integrated film 100 may be in the form of a film, a sheet, a tape, or the like. In the dicing/die-bonding integrated film 100, the supporting film 20 may be provided on a surface of the second adhesive layer 10 on the side opposite to the first adhesive layer 30. A covering film may be provided instead of the supporting film 20. As the covering film, a film having the same material and thickness as those of the supporting film 20 can be used.

Examples of the base material layer 40 in the dicing tape 50 include plastic films such as a polytetrafluoroethylene film, a polyethylene terephthalate film, a polyethylene film, a polypropylene film, a polymethylpentene film, and a polyimide film. The base material layer 40 may be subjected to a surface treatment such as primer application, UV treatment, corona discharge treatment, polishing treatment, or etching treatment as necessary.

The first adhesive layer 30 in the dicing tape 50 is not particularly limited as long as it has a sufficient adhesive strength to prevent the semiconductor chip from scattering during dicing, and has a low adhesive strength that does not damage the semiconductor chip in the subsequent semiconductor chip pickup step, and those conventionally known in the field of dicing tapes can be used. The first adhesive layer 30 may be a first adhesive layer made of a pressure sensitive adhesive or a first adhesive layer made of an ultraviolet curable adhesive. In a case where the first adhesive layer is a first adhesive layer made of an ultraviolet curable adhesive, the first adhesive layer can have its tackiness reduced in adhesiveness by being irradiated with ultraviolet rays.

The thickness of the dicing tape 50 (the base material layer 40 and the first adhesive layer 30) may be 60 to 150 μm or 70 to 130 μm from a viewpoint of economic efficiency and film handing property.

The dicing/die-bonding integrated film 100 illustrated in FIG. 2 can be obtained by a production method that includes a step of preparing a film adhesive 10A and a dicing tape 50 including a base material layer 40 and a first adhesive layer 30 provided on the base material layer 40, and a step of bonding the film adhesive 10A and the first adhesive layer 30 of the dicing tape 50 together. As a method for bonding the film adhesive 10A and the first adhesive layer 30 of the dicing tape 50 together, a conventional method can be used.

### [Method for Producing Semiconductor Device]

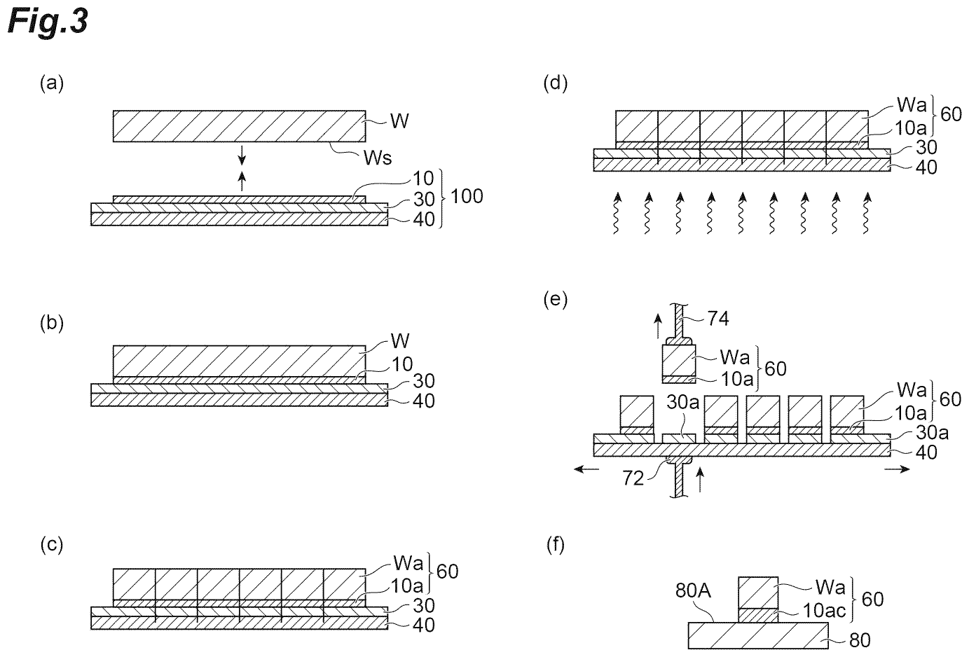

(a) to (f) in FIG. 3 are cross-sectional views schematically illustrating a series of steps for producing a semiconductor device. A method for producing a semiconductor device includes: attaching the second adhesive layer 10 of the above dicing/die-bonding integrated film 100 to a semiconductor wafer W (wafer laminate step, see (a) and (b) in FIG. 3); dicing the semiconductor wafer W with the second adhesive layer 10 attached to prepare a plurality of individual adhesive piece-attached semiconductor chips 60 (dicing step, see (c) in FIG. 3); and bonding the adhesive piece attached semiconductor chips 60 to a support member 80 via an adhesive piece 10a (semiconductor chip bonding step, see (f) in FIG. 3). The method for producing a semiconductor device may further include, as necessary, between the dicing step and the semiconductor chip bonding step, a step of irradiating the first adhesive layer 30 with ultraviolet rays (through the base material layer 40) (ultraviolet irradiation step, see (d) in FIG. 3); a step of picking up the adhesive piece-attached semiconductor chip 60 from the first adhesive layer 30a (pickup step, see (e) in FIG. 3); and a step of thermally curing the adhesive piece 10a on the adhesive piece-attached semiconductor chip 60 bonded to the support member 80 (thermal curing step).

### (Wafer Laminate Step)

In this step, first, the dicing/die-bonding integrated film 100 is disposed in a predetermined device. Subsequently, a surface Ws of the semiconductor wafer W is attached to the second adhesive layer 10 of the dicing/die-bonding integrated film 100 (see (a) and (b) in FIG. 3). A circuit surface of the semiconductor wafer W may be provided on the surface opposite to the surface Ws.

Examples of the semiconductor wafer W include monocrystalline silicon, polycrystalline silicon, various ceramics, and compound semiconductors such as gallium arsenide.

### (Dicing Step)

In this step, the semiconductor wafer W and the second adhesive layer 10 are diced into individual pieces (see (c) in FIG. 3). The adhesive piece-attached semiconductor chip 60 includes a semiconductor chip Wa and an adhesive piece 10a. The semiconductor chip Wa is obtained by singulating the semiconductor wafer W, and the adhesive piece 10a is obtained by singulating the second adhesive layer 10. Further, a part of the first adhesive layer 30, or the entire first adhesive layer 30 and a part of the base material layer 40 may be cut. A first adhesive layer 30a illustrated in (c) in FIG. 3 is obtained by singulating the first adhesive layer 30. As described above, the dicing/die-bonding integrated film 100 also functions as a dicing sheet.

### (Ultraviolet Irradiation Step)

In a case where the first adhesive layer 30 is an ultraviolet curable first adhesive layer, the method for producing a semiconductor device may include an ultraviolet irradiation step. In this step, the first adhesive layer 30 is irradiated with ultraviolet rays (through the base material layer 40) (see (d) in FIG. 3). In the ultraviolet irradiation, the wavelength of the ultraviolet ray may be 200 to 400 nm. In the conditions for ultraviolet irradiation, an intensity and an irradiation amount may be in a range of 30 to 240 mW/cm² and a range of 50 to 500 mJ/cm², respectively.

### (Pickup Step)

In this step, by expanding the base material layer 40, the individual adhesive piece-attached semiconductor chips 60 are separated from each other, while the adhesive piece-attached semiconductor chip 60 pushed up by a needle 72 from a side of the base material layer 40 is sucked by a suction collet 74 and picked up from the first adhesive layer 30a (see (e) in FIG. 3). The first adhesive layer 30a can remain on the base material layer 40 after the adhesive piece-attached semiconductor chip 60 is picked up. In this step, it is not necessary to expand the base material layer 40, but pick-up properties can be further improved by expanding the base material layer 40.

The amount of projection by the needle 72 can be appropriately set. Furthermore, from a viewpoint of securing sufficient pickup capability even for an ultrathin wafer, for example, two-stage or three-stage push-up may be performed. Further, the adhesive piece-attached semiconductor chip 60 may be picked up by a method other than the method using the suction collet 74.

### (Semiconductor Chip Bonding Step)

In this step, the picked-up adhesive piece-attached semiconductor chip 60 is bonded to the support member 80 via the adhesive piece 10a by thermocompression bonding (see (f) in FIG. 3). A plurality of adhesive piece-attached semiconductor chips 60 may be bonded to the support member 80.

The heating temperature in thermocompression bonding may be, for example, 80 to 160° C. The load in thermocompression bonding may be, for example, 5 to 50 N. The heating time in thermocompression bonding may be, for example, 0.5 to 20 seconds.

### (Thermal Curing Step)

In this step, the adhesive piece 10a on the adhesive piece-attached semiconductor chip 60 bonded to the support member 80 is thermally cured. By thermally curing the adhesive piece 10a that bonds the semiconductor chip Wa and the support member 80 or a cured article 10ac of the adhesive piece, a stronger bonding and fixation can be achieved. Further, in a case where the component (A) is silver particles (preferably, silver particles produced by a reduction method), a sintered body of silver particles tends to be more easily obtained by thermally curing the adhesive piece 10a or the cured article 10ac of the adhesive piece. In a case where thermosetting is performed, curing may be performed by simultaneously applying pressure. The heating temperature in this step can be appropriately changed depending on the components of the adhesive piece 10a. The heating temperature may be, for example, 60 to 200° C., 80 to 190° C., or 100 to 180° C. The heating time may be, for example, 1 to 120 minutes, 5 to 100 minutes, 10 to 80 minutes, or 15 to 60 minutes. Note that the temperature or the pressure may be changed stepwise.

The adhesive piece 10a can be cured through the semiconductor chip bonding step or the heat curing step to become a cured article 10ac of the adhesive piece. In a case where the component (A) is silver particles (preferably, silver particles produced by a reduction method), the cured article 10ac of the adhesive piece may contain a sintered body of silver particles. Therefore, the obtained semiconductor device can have excellent heat dissipation property.

The method for producing a semiconductor device may include a step of electrically connecting a tip of a terminal portion (an inner lead) of the support member and an electrode pad on a semiconductor element with a bonding wire (wire bonding step) as necessary. As the bonding wire, for example, gold wire, aluminum wire, copper wire, or the like is used. The temperature when the wire bonding is performed may be within a range of 80 to 250° C. or 80 to 220° C. The heating time may be several seconds to several minutes. The wire bonding may be performed using both vibration energy by ultrasonic waves and bonding energy by applied pressure in a state of being heated within the above temperature range.

The method for producing a semiconductor device may include a step of sealing the semiconductor element with a sealing material (sealing step) as necessary. This step is performed to protect the semiconductor element or the bonding wire mounted on the support member. This step can be performed by molding the resin for sealing (sealing resin) using a mold. The sealing resin may be, for example, an epoxy-based resin. The support member and residues are embedded by the heat and pressure during sealing, and peeling due to bubbles at the bonding interface can be prevented.

The method for producing a semiconductor device may include a step of completely curing the sealing resin that is insufficiently cured in the sealing step (post-curing step) as necessary. Even in a case where the adhesive piece is not heat-cured in the sealing step, in this step, the adhesive piece is heat-cured together with the curing of the sealing resin, so that bonding and fixation can be achieved. The heating temperature in this step can be appropriately set depending on the type of the sealing resin, and may be, for example, within a range of 165 to 185° C., and the heating time may be about 0.5 to 8 hours.

The method for manufacturing a semiconductor device may include a step of heating an adhesive piece-attached semiconductor element bonded to the support member using a reflow furnace (heating and melting step) as necessary. In this step, the semiconductor device sealed with a resin may be surface-mounted on the support member. Examples of a surface mounting method include reflow soldering in which solder is supplied in advance onto a printed wiring board, then heated and melted by hot air or the like to perform soldering. Examples of the heating method include hot air reflow and infrared reflow. Further, the heating method may be one that heats the entire portion or one that heats a local portion. The heating temperature may be, for example, within a range of 240 to 280° C.

### [Semiconductor Device]

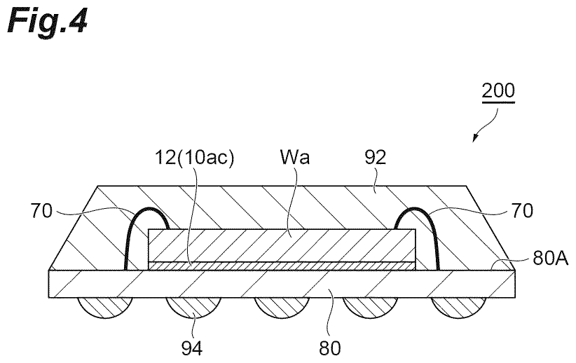

FIG. 4 is a schematic cross-sectional view illustrating one embodiment of a semiconductor device. A semiconductor device 200 illustrated in FIG. 4 includes a semiconductor chip Wa, a support member 80 on which the semiconductor chip Wa is mounted, and an adhesive member 12. The adhesive member 12 is provided between the semiconductor chip Wa and the support member 80, and adheres the semiconductor chip Wa and the support member 80. The adhesive member 12 is a cured article of a film adhesive (a cured article 10ac of an adhesive piece). A connection terminal (not illustrated) of the semiconductor chip Wa may be electrically connected to an external connection terminal (not illustrated) via a wire 70. The semiconductor chip Wa may be sealed by a sealing material layer 92 formed of a sealing material. Solder balls 94 may be formed on a surface of the support member 80 opposite to a surface 80A for electrical connection to an external substrate (mother board) (not illustrated).

The semiconductor chip Wa (semiconductor element) may be, for example, an IC (integrated circuit) or the like. Examples of the support member 80 include a lead frame such as a 42-alloy lead frame and a copper lead frame; a plastic film such as polyimide resin and epoxy resin; a modified plastic film obtained by impregnating a base material such as a glass nonwoven fabric with a plastic such as polyimide resin or epoxy resin and curing the plastic; and a ceramic such as alumina.

Since the semiconductor device 200 includes a cured article of the above film adhesive as an adhesive member, the semiconductor device has excellent heat dissipation.

### EXAMPLES

Hereinafter, the present disclosure will be specifically described based on examples, but the present disclosure is not limited thereto.

### Examples 1 to 4 and Comparative Examples 1 to 3

### <Preparation of Adhesive Varnish>

A raw material varnish was prepared by adding cyclohexanone as an organic solvent to the components (A), (B), (C), and (D) in the symbols and composition ratios (unit: parts by mass) shown in Tables 1 and 2. The raw material varnish was stirred at a mixing temperature of 70° C. at a rotation speed of 4000 rpm for 20 minutes using a Homo Disper (T.K. HOMO MIXER MARK II manufactured by Tajima Chemical Machinery Co., Ltd.) to obtain an adhesive varnish. Next, the adhesive varnish was allowed to stand until the temperature reached 20 to 30° C., the component (E) and the component (F) were then added to the adhesive varnish, and the mixture was stirred overnight at 250 rpm using a Three-One Motor. In this way, an adhesive varnish having a total content of the components (A), (B), (C), and (D) of Examples 1 to 4 and Comparative Examples 1 to 3 of 61% by mass was prepared.

Note that the symbols for each component in Tables 1 and 2 mean the following.

### Component (A): Metal Particles

A1: Silver particles AG-3-1F (trade name, manufactured by DOWA ELECTRONICS MATERIALS CO., LTD., shape: spherical, average particle diameter (laser 50% particle diameter (D₅₀)): 1.5 μm)

### Component (B): Thermosetting Resin

B1: EXA-830CRP (trade name, manufactured by DIC Corporation, bisphenol F epoxy resin, epoxy equivalent: 159 g/eq, liquid at 25° C.)
B2: N-500P-10 (trade name, manufactured by DIC Corporation, cresol novolac epoxy resin, epoxy equivalent: 204 g/eq, softening point: 84° C.)

### Component (C): Curing Agent

C1: MEH-7800M (trade name, manufactured by Meiwa Chemical Co., Ltd., phenyl aralkyl type phenolic resin, hydroxyl group equivalent: 174 g/eq, softening point: 80° C.)

### Component (D): Elastomer

D1: SG-P3 solvent modified product (trade name, manufactured by Nagase ChemteX Corporation, acrylic rubber, weight-average molecular weight: 800000, Tg: 15° C.)

### Component (E): Coupling Agent

E1: Z-6119 (trade name, Dow Corning Toray Co., Ltd., ureidopropyltrialkoxysilane)

### Component (F): Curing Accelerator

F1:1B2MZ (trade name, manufactured by Shikoku Chemicals Corporation, 1-benzyl-2-methyl-1H-imidazole)

### <Calculation of % by Volume>

The content of the component (A) (% by volume) was calculated from the following formula (I), where the density of the film adhesive was x (g/cm³), the density of the component (A) was y (g/cm³), and the mass ratio of the component (A) in the film adhesive was z (% by mass). Note that, the mass ratio of the component (A) in the film adhesive was determined by performing thermogravimetric analysis using a thermogravimetric differential thermal analyzer (TG-DTA). Further, the density of the film adhesive and the component (A) was determined by measuring the mass and density using a hydrometer.

$$Content of component ( A ) ( \% by volume ) = ( x / y ) \times z \qquad ( I )$$

Measurement conditions of TG-DTA: temperature range 30 to 600° C. (heating rate 30° C./min), maintained at 600° C. for 20 minutes
Air flow rate: 300 mL/min
Thermogravimetric differential thermal analyzer: TG/DTA220 manufactured by Seiko Instruments Inc.
Hydrometer: EW-300SG manufactured by Alfa Mirage Co., Ltd.

### (Production of Laminate)

A film adhesive was produced using the adhesive varnish of Examples 1 to 4 and Comparative Examples 1 to 3. Each adhesive varnish was subjected to vacuum defoaming, and the subsequent adhesive varnish was applied onto the release-treated polyethylene terephthalate (PET) film (thickness: 38 μm) as the supporting film. The applied adhesive varnish was heated and dried in two stages, that is, at 90° C. for 5 minutes and then at 130° C. for 5 minutes, and a polyethylene (PE) film (thickness:) was then laminated on the top of the adhesive that had turned into a film, to obtain a laminate having the film adhesive of Examples 1 to 4 and Comparative Examples 1 to 3 having a thickness of 25 μm in the B-stage state and a PE film thereon, on the PET film. Further, the equivalent ratio of the epoxy resin and the phenolic resin in the film adhesive of Examples 1 to 4 and Comparative Examples 1 to 3 at this time was 1.25.

### <Measurement of Shear Viscosity of Film Adhesive at 110° C.>

The film adhesives (thickness: 25 μm) of Examples 1 to 4 and Comparative Examples 1 to 3 were each cut into a predetermined size to prepare 12 film pieces. Then, 12 film pieces were laminated on a hot plate at 70° C. using a rubber roll to prepare a laminate having a thickness of 300 μm. Next, the laminate was punched with a φ10 mm punch to produce a sample, and the shear viscosity of the produced sample at 110° C. was measured using a rotary viscoelasticity measurement device (manufactured by TA Instruments Japan Inc., trade name: ARES-RDA) under the following measurement conditions. Note that, during gap setting, the gap was adjusted so that the load applied to the sample was 10 g. The results are shown in Tables 1 and 2.

### (Measurement Conditions)

Disk plate: aluminum, 8 mm φ
Measurement frequency: 1 Hz
Temperature rising rate: 5° C./min
Strain: 5%
Measurement temperature: 35 to 180° C.
Initial load: 10 g

### <Evaluation of Storage Elastic Modulus>

### (Production of Evaluation Sample)

A plurality of the film adhesives of Example 1 to 4 and Comparative Example 1 to 3 were laminated with a rubber roll to prepare a laminated film having a thickness of 200 μm or more. Next, the laminated film was heated at 110° C. for 1 hour in a constant temperature dryer, and further heated at 170° C. for 3 hours, and the thermally cured laminated product was cut into 4 mm×30 mm to obtain a sample for storage elastic modulus measurement.

### (Measurement of Storage Elastic Modulus of Test Sample)

The storage elastic modulus of the obtained samples at 35° C. and 110° C. were measured using a dynamic viscoelasticity evaluation device (manufactured by UBM, trade name: Rheogel-E4000) under the following measurement conditions. The results are shown in Tables 1 and 2.

### (Measurement Conditions)

Basic frequency: 10 Hz
Measurement mode: strain dependency
Temperature rising rate: 3° C./min
Measurement temperature: 30 to 270° C.

### <Evaluation of Die Shear Strength>

### (Production of Evaluation Sample)

The semiconductor wafer in the obtained integrated film was diced into pieces having a size of 5 mm×5 mm, and then a lead frame (LF810 die pad downset) was prepared, the lead frame was temporarily bonded at a stage temperature of 70° C. for heating and a press-bonding time of 3 s, and then an adhesive piece-attached semiconductor chip was bonded to the lead frame via an adhesive piece under conditions of a stage temperature for heating of 120° C., a press-bonding time of 5 seconds, and a press-bonding load of 0.01 MPa. Thereafter, the lead frame to which the semiconductor chip was press-bonded was pressurized and heated under the conditions of a temperature of 110° C. and a pressure of 0.7 MPa for 1 hour and then under the conditions of a temperature of 170° C. and a pressure of 0.7 MPa for 3 hours to thermally cure the adhesive piece, thereby obtaining an evaluation sample.

### (Evaluation of the Die Shear Strength of Test Sample)

The evaluation sample set at a stage temperature of 265° C. and thermally cured was allowed to stand on the stage for 20 seconds using a die shear strength measurement device (manufactured by Dage), and then a fracture test was performed, and the results are shown in Table 1.

### <Evaluation of 90° C. Peel Strength>

DAF/PE side: The DAF was cut into a size of 20 mm×100 mm in a state of being laminated with the covering film after the forming step. Thereafter, a test piece with a double-sided tape was prepared, the PET was peeled off, and the DAF surface was attached to a double-sided tape, and a 90° C. peel test was performed under the conditions of room temperature (25° C.) and a peeling rate of 50 mm/min using a 90° C. peel tester (manufactured by TESTER SANGYO CO., LTD.). The results are shown in Table 1.

DAF/PET side: Almost the same as the above method, the DAF obtained by peeling off the PE from the prepared test piece having double-sided tape was attached to the double-sided tape, and the rest is the same as the above.

### <Evaluation of DAF/PE Adhesion>

The evaluation was performed visually on the sample after the molding step. Evaluation criteria were as follows. The results are shown in Table 1.
A: Delamination is hardly observed.
B: Some delamination is observed.
C: Delamination occurs over a wide area.

### <Measurement of Thermal Conductivity>

### (Production of Film for Thermal Conductivity Measurement)

A plurality of the film adhesives of Example 1 to 4 and Comparative Example 1 to 3 were laminated using a rubber roll to prepare a laminated film having a thickness of 200 μm or more. Next, the laminated film was cut into 1 cm×1 cm, and the cut laminated film was thermally cured in a constant temperature dryer at 110° C. for 1 hour and, further heated at 170° C. for 3 hours to obtain a film for measuring thermal conductivity in the C-stage state.

### (Calculation of Thermal Conductivity)

The thermal conductivity X of the film for thermal conductivity measurement in the thickness direction was calculated by the following formula. The results are shown in Tables 1 and 2.

$$Thermal conductivity λ ( W / ( m \cdot K ) ) = thermal diffusivity α ( {m}^{2} / s ) \times specific heat Cp ( J / ( kg \cdot K ) ) \times density ρ ( g / {cm}^{3} )$$

Note that, the thermal diffusivity α, specific heat Cp, and density ρ were measured by the following methods. A large thermal conductivity λ means that the semiconductor device is superior in heat dissipation.

### (Measurement of Thermal Diffusivity α)

A measurement sample was produced by blackening treatment of both sides of the film for thermal conductivity measurement with graphite spray. The thermal diffusivity α of the film for thermal conductivity measurement of the measurement sample was determined by a laser flash method (xenon flash method) under the following conditions using the following measurement device.
Measurement device: thermal diffusivity measurement device (manufactured by NETZSCH Japan K.K., trade name: LFA447 nanoflash)
Pulse width of pulsed light irradiation: 0.1 ms
Applied voltage for pulsed light irradiation: 236 V
Treatment of measurement sample: blackening both sides of film for thermal conductivity measurement with graphite spray
Measurement atmosphere temperature: 35° C.

### (Measurement of Specific Heat Cp (25° C.))

The specific heat Cp (25° C.) of the film for measuring thermal conductivity was determined by performing differential scanning calorimetry (DSC) under the following conditions using the following measurement device.
Measurement device: differential scanning calorimeter (manufactured by PerkinElmer Japan G.K., trade name: Pyris 1)
Reference material: sapphire
Temperature rising rate: 10° C./min
Heating temperature range: 35° C. to 75° C.

### (Measurement of Density φ

The density ρ of the film for thermal conductivity measurement was measured by the Archimedes method under the following conditions using the following measurement device.
Measurement device: electronic densimeter (manufactured by Alfa Mirage Co., Ltd., trade name: SD200L)
Water temperature: 25° C.

TABLE 1

| | | Example 1 | Example 2 | Example 3 | Example 4 |
|---|---|---|---|---|---|
| Component (A) | A1 | 82.00 | 83.00 | 84.00 | 85.00 |
| Component (B) | B1 | 4.17 | 3.99 | 3.79 | 3.57 |
| | B2 | 2.78 | 2.50 | 2.23 | 1.99 |
| Component (C) | C1 | 5.65 | 5.29 | 4.93 | 4.57 |
| Component (D) | D1 | 5.36 | 5.19 | 5.02 | 4.84 |
| Component (E) | E1 | 0.025 | 0.025 | 0.025 | 0.025 |
| Component (F) | F1 | 0.005 | 0.005 | 0.005 | 0.005 |
| Content of component (A) [% by mass] | | 82.0 | 83.0 | 84.0 | 85.0 |
| Content of component (A) [% by volume] | | 33.6 | 35.2 | 36.8 | 38.6 |
| B1/A × 100 | | 5.0 | 4.8 | 4.5 | 4.2 |
| B1/B2 | | 1.5 | 1.6 | 1.7 | 1.8 |
| Attached state of DAF/PE | | A | A | A | A |
| Die shear strength [MPa] | | 3.57 | 2.42 | 2.38 | 2.30 |
| Shear viscosity @ 110° C. [Pa · s] | | 15623 | 23523 | 28872 | 31592 |
| Storage elastic | @35° C. | 4578.7 | 4975.6 | 4568.5 | 4721.2 |
| modulus [MPa] | @265° C. | 430.7 | 582.7 | 634.8 | 689.6 |
| Thermal conductivity [W/(m · k)] | | 9.5 | 13.0 | 14.7 | 18.6 |
| 90° C. | DAF/PE | 0.083 | 0.091 | 0.089 | 0.064 |
| peel strength | DAF/PET | 0.037 | 0.040 | 0.027 | 0.029 |

TABLE 2

| | | Comparative | Comparative | Comparative |
|---|---|---|---|---|
| | | example 1 | example 2 | example 3 |
| Component (A) | A1 | 80.00 | 85.00 | 86.00 |
| Component (B) | B1 | 4.72 | 3.35 | 3.08 |
| | B2 | 3.15 | 2.23 | 2.05 |
| Component (C) | C1 | 6.39 | 4.54 | 4.17 |
| Component (D) | D1 | 5.71 | 4.84 | 4.67 |
| Component (E) | E1 | 0.025 | 0.025 | 0.025 |
| Component (F) | F1 | 0.005 | 0.005 | 0.005 |
| Content of component | | 80.0 | 85.0 | 86.0 |
| (A) [% by mass] | | | | |
| Content of component | | 30.8 | 38.6 | 40.5 |
| (A) [% by volume] | | | | |
| B1/A × 100 | | 5.9 | 3.9 | 3.5 |
| B1/B2 | | 1.5 | 1.5 | 1.5 |
| Attached | | B | C | C |
| state of DAF/PE | | | | |
| Die shear | | 2.46 | 2.54 | — |
| strength [MPa] | | | | |
| Shear viscosity @ | | 15623 | 20003 | — |
| 110° C. [Pa · s] | | | | |
| Storage elastic | @35° C. | — | — | — |
| modulus [MPa] | | | | |
| Storage elastic | @265° C. | — | — | — |
| modulus [MPa] | | | | |
| Thermal conductivity | | 7.1 | 20.7 | 2.34 |
| [W/(m · k)] | | | | |
| 90° C. | DAF/PE | — | — | — |
| peel strength | | | | |
| 90° C. | DAF/PET | 0.026 | 0.023 | — |
| peel strength | | | | |

In Tables 1 and 2, the “content of the component (A) [% by mass]” and the “content of the component (A) [% by volume]” were both based on the total amount of the film adhesive (the total amount of the components (A), (B), (C), (D), (E), and (F)). The film adhesive of Examples 1 to 4 in which the content of the component (A) was 80.0% by mass or more and the value of B1/A×100 was in the range of 4.0 to 5.5 had good thermal conductivity and excellent adhesion to the covering film as compared with the film adhesive of Comparative Examples 1 to 3 not satisfying such conditions.

From the above, it has been confirmed that the film adhesive of the present disclosure can be used to produce a semiconductor device having excellent in heat dissipation properties and having excellent adhesion.

### INDUSTRIAL APPLICABILITY

According to the present disclosure, a film adhesive having excellent adhesion is provided, and a semiconductor device excellent in heat dissipation can be produced. Further, according to the present disclosure, a dicing/die-bonding integrated film using such a film adhesive is provided. Furthermore, according to the present disclosure, a semiconductor device using such a film adhesive or a dicing/die-bonding integrated film and a method for producing the same are provided.

### REFERENCE SIGNS LIST

10: adhesive layer, 10A: film adhesive, 10a: adhesive piece, 10ac: cured article of adhesive piece, 12: adhesive member, 20: supporting film, 30, 30a: first adhesive layer, 40: base material layer, 50: dicing tape, 60: adhesive piece-attached semiconductor chip, 70: wire, 72: needle, 74: suction collet, 80: support member, 92: sealing material layer, 94: solder ball, 100: dicing/die-bonding integrated film, 200: semiconductor device, W: semiconductor wafer, Wa: semiconductor chip

1. A film adhesive comprising metal particles, an epoxy resin, a phenolic resin, and an elastomer, wherein
a content of the metal particles is 80.0% by mass or more based on a mass of the film adhesive,
the epoxy resin includes a first epoxy resin being liquid at 25° C. and a second epoxy resin being solid at 25° C., and
a content of the first epoxy resin is 4.0 to 5.5 parts by mass when the content of the metal particles is 100 parts by mass.

2. The film adhesive according to claim 1, wherein the content of the first epoxy resin is 1.5 parts by mass or more when the content of the second epoxy resin is 1 part by mass.

3. The film adhesive according to claim 1, wherein the content of the metal particles is 26 to 38 vol % based on a volume of the film adhesive.

4. The film adhesive according to claim 1, wherein the metal particles are silver particles.

5. The film adhesive according to claim 1, wherein an equivalent ratio of the epoxy resin to the phenolic resin is 1.2 or more.

6. The film adhesive according to claim 1 having a thickness of 5 to 40 μm.

7. The film adhesive according to claim 1, wherein a thermal conductivity at 25° C.±1C after being thermally cured at 170° C. for 3 hours is 7 W/(m·K) or more.

8. The film adhesive according to claim 1, wherein the content of the elastomer is 15.0% by mass or less based on the mass of the film adhesive.

9. A dicing/die-bonding integrated film having a laminate structure including a base material layer, a first adhesive layer, and a second adhesive layer in order, wherein the second adhesive layer is composed of the film adhesive according to claim 1.

10. The dicing/die-bonding integrated film according to claim 9, further comprising a covering film provided to cover the second adhesive layer.

11. A semiconductor device comprising:
a semiconductor chip;
a support member on which the semiconductor chip is mounted; and
an adhesive member provided between the semiconductor chip and the support member and bonding the semiconductor chip and the support member to each other,
wherein the adhesive member is a cured article of the film adhesive according to claim 1.

12. A method for producing a semiconductor device, the method comprising:
attaching the second adhesive layer of the dicing/die-bonding integrated film according to claim 9 to a semiconductor wafer;
singulating a laminate of the semiconductor wafer and the second adhesive layer into pieces to obtain an adhesive piece-attached semiconductor chip composed of a semiconductor chip and an adhesive piece; and
bonding the semiconductor chip to a support member via the adhesive piece.
